(19) United States
(12) Patent Application Publication
(10) Pub. No.: US 2022/0208589 A1
(43) Pub. Date: Jun. 30, 2022

(54) SUBSTRATE GRIPPING APPARATUS AND LIQUID PROCESSING APPARATUS, AND SUBSTRATE PROCESSING EQUIPMENT INCLUDING SAME

(71) Applicant: SEMES CO., LTD., Cheonan-si (KR)

(72) Inventors: Se Min KANG, Cheonan-si (KR); Gu Yeol AN, Busan (KR)

(73) Assignee: SEMES CO., LTD., Cheonan-si (KR)

(21) Appl. No.: 17/555,302

(22) Filed: Dec. 17, 2021

(30) Foreign Application Priority Data
Dec. 24, 2020 (KR) 10-2020-0183643

(51) Int. Cl. H01L 21/687; H01L 21/67; H01L 21/677

(52) U.S. Cl. CPC H01L 21/687; H01L 21/67742; H01L 21/67017

(57) ABSTRACT

An apparatus and a method of reducing the replacement cycle due to abrasion of chuck pins that support a lateral surface of a substrate are proposed. A substrate gripping apparatus for gripping the substrate in substrate processing equipment includes a chuck, a gear box configured to be movable with respect to the chuck, a rotation gear provided inside the gear box, chuck pins configured to be rotatable while being coupled to the rotation gear and to be brought into contact with a lateral surface of the substrate. According to the embodiment of the present disclosure, the substrate is configured such that the lateral surface thereof is supported by various positions of each of the chuck pins. Therefore, the life of the chuck pins can be improved and maintenance costs can be reduced.

### CROSS REFERENCE TO RELATED APPLICATION

The present application claims priority to Korean Patent Application No. 10-2020-0183643, filed Dec. 24, 2020, the entire contents of which is incorporated herein for all purposes by this reference.

### BACKGROUND OF THE INVENTION

### Field of the Invention

The present disclosure relates to a substrate gripping apparatus and a liquid processing apparatus, and substrate processing equipment including the same. More particularly, the present disclosure relates to a substrate gripping apparatus and a liquid processing apparatus, and substrate processing equipment including the same, the substrate gripping apparatus being capable of solving the problem of a reduction in the life of chuck pins in contact with a substrate that may be caused by abrasion of the chuck pins.

### Description of the Related Art

A semiconductor (or display) manufacturing process is a process for manufacturing a semiconductor device on a substrate (e.g., wafer), and includes, for example, exposure, deposition, etching, ion implantation, cleaning, and the like. In particular, various organic and inorganic foreign substances exist on the substrate. In order to improve the manufacturing yield, it is important to effectively remove foreign substances on the substrate.

A cleaning process using a processing liquid (cleaning liquid) is mainly used to remove foreign substances. The cleaning process may be performed by supplying the processing liquid to an upper or lower surface of the substrate while rotating a spin chuck that supports the substrate. After the cleaning process, a rinsing process using a rinsing liquid and a drying process using a drying gas are performed.

A technique of diffusing a chemical liquid from the center of the substrate to the outer periphery thereof by rotating the substrate while supplying the chemical liquid toward upper and lower portions of the substrate is used in the liquid treatment process. For achieving the technique, support pins supporting the lower portion of the substrate and chuck pins gripping the substrate by being in contact with a lateral surface of the substrate. The chuck pins supporting the lateral surface of the substrate may be worn out as the process is repeatedly performed.

### SUMMARY OF THE INVENTION

Accordingly, the present disclosure has been made keeping in mind the above problems occurring in the related art, and the present disclosure is intended to provide an apparatus and a method capable of reducing a replacement cycle due to abrasion of chuck pins that support a lateral surface of a substrate.

The problem to be solved is not limited thereto, and other problems not mentioned will be clearly understood by those skilled in the art from the following description.

A substrate gripping apparatus configured to grip a substrate in substrate processing equipment, the substrate gripping apparatus includes: a chuck configured to be rotatable; a gear box configured to be movable with respect to the chuck; a rotation gear provided inside the gear box; and chuck pins configured to be rotatable while being coupled to the rotation gear, and configured to be brought into contact with a lateral surface portion of the substrate.

The gear box may include: a gear box housing providing a space in which the rotation gear may be disposed; and a linear guide securely coupled to the chuck, and configured to provide a path for rectilinearly moving the gear box housing.

The substrate gripping apparatus may include an angle adjustment gear engaged with the rotation gear, and configured to adjust rotation of the rotation gear.

The angle adjustment gear may be coupled to support pins configured to support a lower portion of the substrate, and rotation of the chuck pins may be controlled by rotation of the support pins.

The substrate gripping apparatus may include a worm gear engaged with the rotation gear, and configured to extend to an outside of the gear box.

The substrate gripping apparatus may include a driving source configured to rotate the worm gear.

The substrate gripping apparatus may include a stopper configured to hold the chuck pins to prevent the rotation of the chuck pins.

The substrate gripping apparatus may include an oil seal configured to prevent chemical liquid from leaking into the gear box.

A liquid processing apparatus may include: a substrate support unit configured to support a substrate; and a processing liquid supply unit configured to supply chemical liquid to the substrate, wherein the substrate support unit may include: a chuck configured to be rotatable; support pins secured to the chuck and configured to support a lower portion of the substrate; a gear box configured to be movable with respect to the chuck; a rotation gear provided inside the gear box; and chuck pins configured to be rotatable while being coupled to the rotation gear, and configured to be brought into contact with a lateral surface portion of the substrate.

Substrate processing equipment may include an index module including a load port on which a carrier storing a substrate may be loaded, and an index robot configured to transfer the substrate; and a processing module including a buffer unit on which the substrate may be temporarily loaded, and a process chamber in which a liquid treatment process for the substrate may be performed. The process chamber may include: a substrate support unit configured to support the substrate; and a processing liquid supply unit configured to supply chemical liquid to the substrate. The substrate support unit may include: a chuck configured to be rotatable; support pins secured to the chuck and configured to support a lower portion of the substrate; a gear box configured to be movable with respect to the chuck; a rotation gear provided inside the gear box; and chuck pins configured to be rotatable while being coupled to the rotation gear, and configured to be brought into contact with a lateral surface portion of the substrate.

According to the embodiment of the present disclosure, the substrate is configured such that the lateral surface thereof is supported by various positions of each of the chuck pins. Therefore, the life of the chuck pins can be improved, and the maintenance costs can be reduced.

The effect of the present disclosure is not limited to the above description, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view schematically showing a structure of a chuck provided to support a substrate in a liquid processing apparatus.

FIGS. 2 and 3 are views showing a substrate gripping apparatus according to an embodiment of the present disclosure.

FIGS. 4 and 5 are views showing a substrate gripping apparatus according to an embodiment of the present disclosure.

FIGS. 6 and 7 are views showing a substrate gripping apparatus including a rotation-driving type gear box according to an embodiment of the present disclosure.

FIG. 8 is a view schematically showing a structure of the liquid processing apparatus.

FIG. 9 is a view schematically showing a structure of substrate processing equipment.

FIGS. 10 and 11 are views showing a substrate gripping apparatus in which a stopper is implemented according to an embodiment of the present disclosure.

### DETAILED DESCRIPTION OF THE INVENTION

Hereinbelow, exemplary embodiments of the present disclosure will be described in detail with reference to the accompanying drawings such that the present disclosure can be easily embodied by one of ordinary skill in the art to which the present disclosure belongs. However, the present disclosure may be changed to various embodiments and the scope and spirit of the present disclosure are not limited to the embodiments described hereinbelow.

In the following description, if it is decided that the detailed description of known function or configuration related to the present disclosure makes the subject matter of the present disclosure unclear, the detailed description is omitted, and the same reference numerals will be used throughout the drawings to refer to the elements or parts with same or similar function or operation.

Furthermore, in various embodiments, an element with same configuration will be described in a representative embodiment by using the same reference numeral, and different configuration from the representative embodiment will be described in other embodiments.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion such as “between” versus “directly between”, “adjacent” versus “directly adjacent”, etc. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

In the flowing description, unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

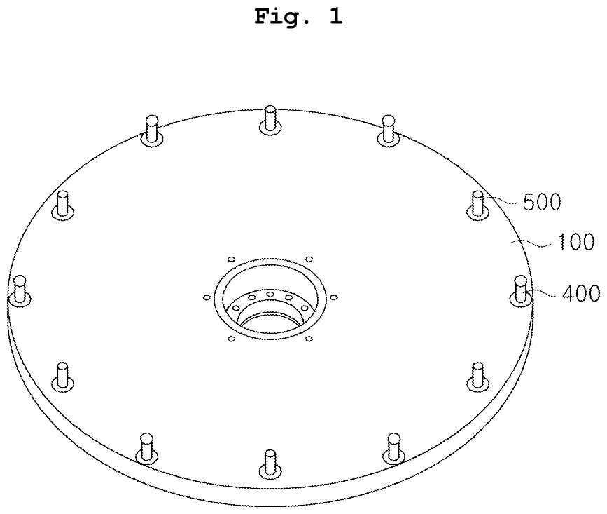

FIG. 1 is a view schematically showing a structure of a chuck provided to support a substrate in a liquid processing apparatus. Referring to FIG. 1, a substrate gripping apparatus includes a chuck 100 as a base, which is provided to secure and rotate a substrate W. Support pins 500 and chuck pins 400 are provided on an upper surface of the chuck 100. The support pins 500 support a lower portion (i.e., a bottom surface) of the substrate W. The chuck pins 400 secure the substrate W by being brought into contact with a lateral surface of the substrate W so as to prevent separation of the substrate W.

As shown in FIG. 1, the support pins 500 are arranged at an outer circumferential portion of the chuck 100 at constant intervals. The chuck pins 400 may be arranged at an outer circumferential portion of the chuck 100 at constant intervals. Normally, the support pins 500 and the chuck pins 400 are fixed on the chuck 100. The chuck pins 400 may be located outside the outer circumferential portion of the chuck 100 where the support pins 500 are provided. For example, the chuck pins 400 may be disposed at a region between an outer perimeter of the chuck 100 and an imaginary circle connecting the support pins 500.

The chuck pins 400 may be rectilinearly moved in a horizontal direction on the basis of a center portion of the chuck 100. Without the substrate W, the chuck pins 400 are located outside the lateral surface of the substrate W (e.g., a wafer). When the substrate W is placed, the chuck pins 400 are located at contact locations closer to the center portion of the substrate W so as to contact a lateral surface of the substrate W. For example, the chuck pins 400 move toward the center of the chuck 100 to secure the substrate W. During time when the chuck pins 400 secure the substrate W, each chuck pin of the chuck pins 400 may contact a corresponding portion of the lateral surface of the wafer W.

For example, when the substrate W to be liquid-processed is loaded on upper portions of the support pins 500, the chuck pins 400 are rectilinearly moved from outer locations to the contact locations and are brought into contact with the lateral surface of the substrate W. The chuck pins 400 grip the substrate W, so that the substrate W on which liquid processing is performed is not separated from its location. When the process for the substrate W is complete, the chuck pins 400 are rectilinearly moved from the contact locations to the outer locations, so that the contact between the chuck pins and the substrate W is released. Meanwhile, the chuck pins 400 may be brought into contact with the substrate W by rotary movement in addition to the rectilinear movement.

In the liquid treatment process (e.g.: cleaning process and coating process) for the substrate W, since the substrate W is rotated, the chuck pins 400 may be worn out due to the contact between the substrate W and the chuck pins 400. When it is difficult to properly grip the substrate W due to the wear of the chuck pins 400 as the process is repeatedly performed, an operator should replace the chuck pins 400.

If the chuck pins 400 are fixed to the chuck 100, so that some portions of the chuck pins 400 in contact with the substrate W may be continuously worn out. Therefore, although wear has occurred only in certain areas, all the chuck pins 400 should be replaced, thus improvement in cost efficiency is necessary. When one portion of each of the chuck pins 400 is worn out, a contact force between the chuck pin and the substrate W is lowered. Therefore, the substrate W is not properly supported and may be spun without traction.

In the embodiment of the present disclosure, the chuck pins 400 are configured to be rotatable, so that the chuck pins may be brought into contact with the substrate W at a plurality of portions thereof rather than a specific portion of each of the chuck pins 400. Hereinbelow, the substrate gripping apparatus including the rotatable chuck pins 400 according to an embodiment of the present disclosure will be described.

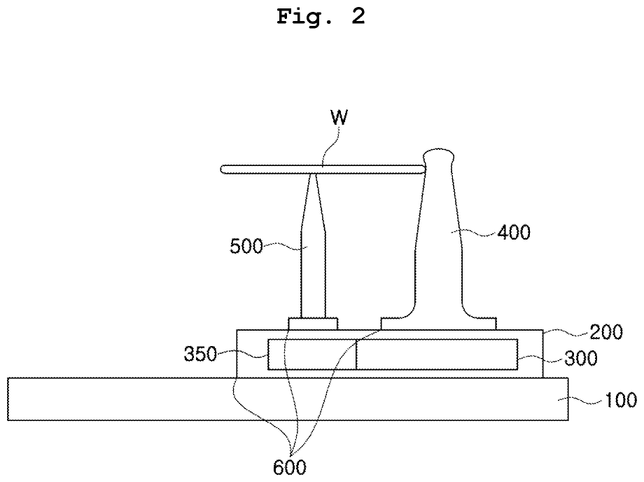

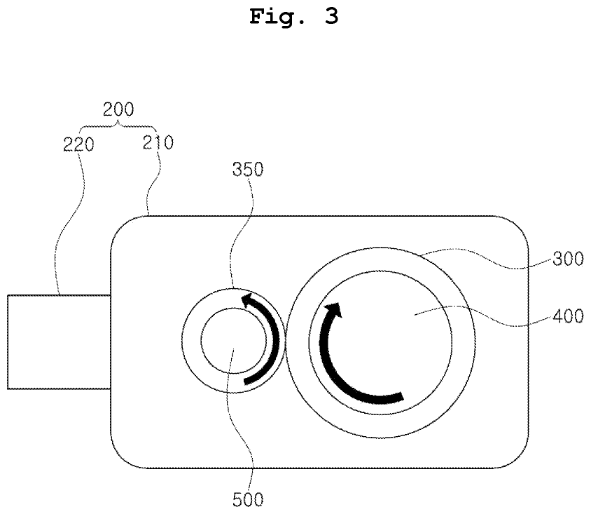

FIGS. 2 and 3 are views showing a substrate gripping apparatus according to an embodiment of the present disclosure. FIG. 2 is a side view showing a structure of the substrate gripping apparatus. FIG. 3 is a top view showing the substrate gripping apparatus.

Referring to FIGS. 2 and 3, in substrate processing equipment, the substrate gripping apparatus provided for gripping the substrate includes the chuck 100, a gear box 200 that is movable with respect to the chuck 100, a rotation gear 300 provided inside the gear box 200, and the chuck pins 400 coupled to the rotation gear 300 and contacting the lateral surface of the substrate W. According to the embodiment, as the chuck pins 400 are configured to rotate by the rotation gear 300, not only a specific portion of each of the chuck pins 400 may contact the substrate W, but various portions located along a rim of the chuck pin 400 may contact the substrate W. In some embodiments, each chuck pin 400 may rotate by the rotation gear 300 during a time when the chuck pin 400 contacts a lateral surface W-LS of the substrate W. For example, each chuck pin 400 may rotatably contact the lateral surface W-LS of the substrate W. Therefore, even when some of the chuck pin 400 is worn out, the chuck pin 400 may support the substrate W at other portions thereof, so that idling of the substrate W may be prevented and the life of the chuck pins 400 may be improved.

As described above, the chuck 100 may be a support on which the chuck pins 400 are provided, and the chuck 100 may be configured to be rotatable. The chuck 100 may include a heater for heating the substrate W. A nozzle may be provided on a center portion of the chuck 100. The nozzle supplies the chemical liquid to a lower surface of the substrate W. The upper portion of the chuck 100 has the support pins 500 supporting the lower portion of the substrate W and the chuck pins 400 supporting the lateral surface of the substrate W.

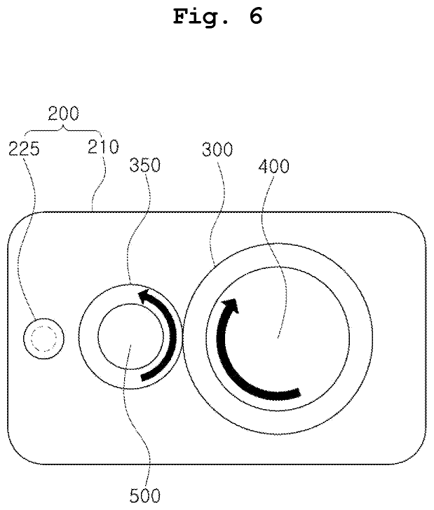

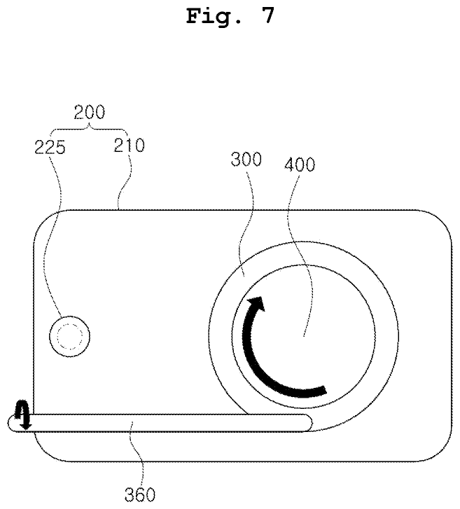

The gear box 200 may be provided on the upper surface of the chuck 100 and may be rectilinearly or rotatably moved with respect to the center portion of the chuck 100. FIGS. 2 to 5 are views showing the gear box 200 in the rectilinear movement, and FIGS. 6 and 7 are views showing the gear box 200 in the rotatable movement. The gear box 200 has a circular opening. The chuck pins 400 are inserted in the circular opening of the gear box 200 and the rotation gear 300 is located inside the gear box 200.

According to the embodiment of the present disclosure, the gear box 200 includes a gear box housing 210 providing a space in which the rotation gear 300 is arranged, and a linear guide 220 securely coupled to the chuck 100 and providing a path to rectilinearly move the gear box housing 210. As shown in FIGS. 2 and 3, the gear box housing 210 is configured to be rectilinearly moved along the linear guide 220, whereby the chuck pins 400 are rectilinearly moved together with the gear box housing 210. A driving source may be provided to supply power for moving the gear box housing 210.

According to the embodiment of the present disclosure, the substrate gripping apparatus includes an angle adjustment gear 350 that is engaged with the rotation gear 300 and controls the rotation of the rotation gear 300. The angle adjustment gear 350 is coupled to the support pins 500 supporting the lower portion of the substrate W. The rotation of a chuck pin 400 may be controlled by the rotation of the support pin 500 adjacent to the chuck pin 400. When the chuck pins 400 must be rotated so that various portions of the chuck pin 400 can be brought into contact with the lateral surface of the substrate W, the chuck pins 400 may be rotated as the support pins 500 are rotated.

The support pin 500 may be rotated manually when a maintenance is performed. The support pin 500 may be rotated with a certain angle (e.g., 90 degrees) to change a contact portion of the chuck pin 500 with respect to the substrate W, in order to avoid partial abrasion of the chuck pin 500.

When the support pin 500 is rotated, the angle adjustment gear 350 is rotated in company with the support in the chuck pin 500. By the rotation of the angle adjustment gear 350, the rotation gear 300 is rotated, which leads to rotation of the chuck pin 500.

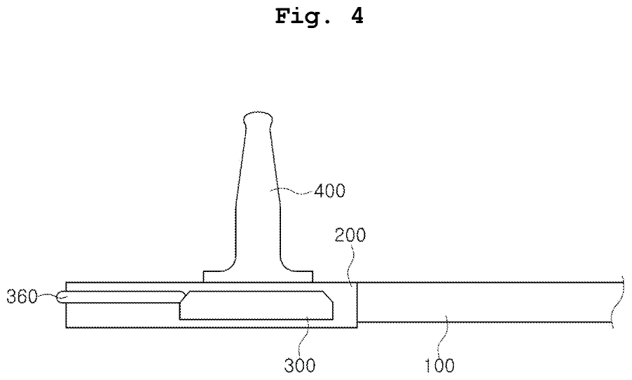

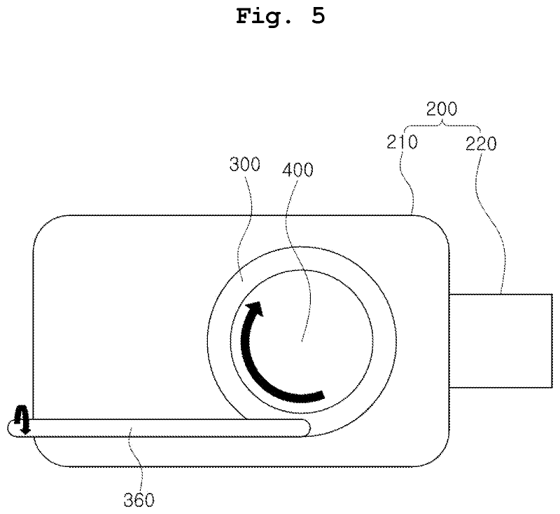

FIGS. 4 and 5 are views showing a substrate gripping apparatus according to an embodiment of the present disclosure. FIG. 4 is a side view showing a structure of the substrate gripping apparatus. FIG. 5 is a top view showing the substrate gripping apparatus.

According to an embodiment of the present disclosure, the substrate gripping apparatus includes a worm gear 360. The worm gear 360 is engaged with the rotation gear 300 and is formed to extend to the outside of the gear box 200. According to the embodiment, the rotation gear 300 fixed to and rotating the chuck pins 400 is engaged with the worm gear 360 and is rotated. The worm gear 360 is formed to extend to the outside of the gear box housing 210.

According to the embodiment of the present disclosure, the substrate gripping apparatus may include a driving source for rotating the worm gear 360. The worm gear 360 is rotated by the driving source to rotate the rotation gear 300 and the chuck pins 400. The worm gear 360 includes a rotation lever to be manually rotated by the operator. Therefore, the worm gear may rotate the rotation gear 300 and the chuck pins 400.

According to the embodiment of the present disclosure, the substrate gripping apparatus may include a stopper holding the chuck pins 400 so as to prevent the rotation of the chuck pins 400. The stopper may hold the chuck pins 400 and the rotation gear 300, so that the chuck pins 400 and the rotation gear 300 are turned from the rotatable state to the non-rotating state. The stopper may be realized in a lever shape, so that whether the chuck pins 400 and the rotation gear 300 are rotatable or not may be controlled.

An oil seal 600 may be provided to prevent the chemical liquid from leaking into the gear box 200. The oil seal 600 seals a space between the chuck 100 and the gear box 200 or spaces into which the chuck pins 400 and the support pins 500 are inserted, thereby preventing the leaking of the chemical liquid into the gear box 200. Therefore, damages caused by the chemical liquid to the rotation gear 300, the angle adjustment gear 350, or the worm gear 360 are prevented.

FIGS. 6 and 7 are the views showing the substrate gripping apparatus including the rotation-driving type gear box 200 according to the embodiment of the present disclosure. The gear box 200 with the shape as shown in FIGS. 2 to 5 is configured to be rectilinearly moved by the linear guide 220. However, the gear box 200 according to the embodiment of the present disclosure may be rotatably coupled to the chuck 100 as shown in FIGS. 6 and 7. The gear box 200 may be rotated on a rotating shaft 225. Each of the chuck pins 400 coupled to the gear box 200 may be configured to be moved from a non-contact location to a contact location with respect to the substrate W in response to whether the substrate W is loaded or not.

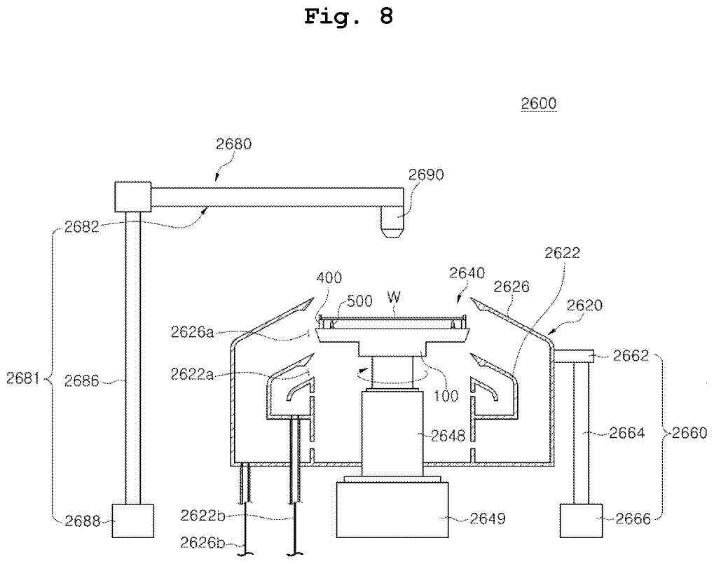

FIG. 8 is a view schematically showing a structure of the liquid processing apparatus.

Referring to FIG. 8, a substrate processing apparatus 2600 provided in a liquid treatment chamber includes a processing container 2620, a substrate support unit 2640, a raising and lowering unit 2660, and a processing liquid supply unit 2680. The substrate processing apparatus 2600 provided in the process chamber 260 for liquid treatment may supply the processing liquid to the substrate W. For example, the processing liquid may be an etchant, a cleaning solution, a rinse solution, and an organic solvent. Etchant or cleaning solution may be a liquid with basic properties and may include sulfuric acid (H2SO4), phosphoric acid (P2O5), hydrofluoric acid (HF), and ammonium hydroxide (NH4OH). The processing liquid may be diluted sulfuric acid peroxide (DSP).

The rinse solution may be de-ionized water (H2O). The organic solvent may be isopropyl alcohol (IPA), i.e., a low surface tension fluid.

The processing container 2620 may provide a processing space in which the substrate is processed. The processing container 2620 may have a barrel shape with an open upper portion. The processing container 2620 may include the outer recovery container 2626 (or first recovery container) and an inner recovery container 2622 (or second recovery container). The recovery containers 2622 and 2626 respectively recover different processing liquids among the processing liquids used in processes. The inner recovery container 2622 is formed in a ring shape surrounding the substrate support unit 2640. The outer recovery container 2626 may be formed in a ring shape surrounding the inner recovery container 2622. An inside space 2622a of the inner recovery container 2622 serves as an inner inlet 2622a through which the processing liquid flows into the inner recovery container 2622. An interspace 2626a located between the inner recovery container 2622 and the outer recovery container 2626 serves as an outer inlet 2626a through which the processing liquid flows into the outer recovery container 2626. Each of the inlets 2622a and 2626a may be located at different height from each other. Recovery lines 2622b and 2626b are respectively connected to lower surfaces of the recovery containers 2622 and 2626. The processing liquid introduced into each of the recovery containers 2622 and 2626 may be reused by being provided into an external processing liquid recycling system (not shown) through the recovery lines 2622b and 2626b.

The substrate support unit 2640 supports the substrate W in the processing space. The substrate support unit 2640 may support and rotate the substrate W during the process. The substrate support unit 2640 includes the chuck 100, the support pins 500, the chuck pins 400, and a rotation driving member. The chuck 100 is formed in a generally circular plate shape.

The support pins 500 may include a plurality of support pins 500. The plurality of support pins 500 is projected from the chuck 100 and supports the lower surface of the substrate W.

The chuck pins 400 are projected from the chuck 100 and support lateral portions of the substrate W. The chuck pins 400 support the lateral portions of the substrate W so as to prevent the substrate W from deviating radially from an original location when the chuck 100 is rotated. The chuck pins 400 are provided to be rectilinearly movable between outer locations and inner locations thereof in a radial direction of the chuck 100. When the substrate W is loaded or unloaded on the chuck 100, the chuck pins 400 are located at the outer locations. When the process for the substrate W is performed, the chuck pins 400 are located at the inner locations. The inner locations are locations where the chuck pins 400 and the lateral portions of the substrate W are brought into contact with each other. The outer locations are locations where the chuck pins 400 and the substrate W are separated from each other.

The rotation driving member 2648 and 2649 rotates the chuck 100. The chuck 100 is rotatable on a central shaft thereof by the rotation driving member 2648 and 2649. The rotation driving member 2648 and 2649 includes a support shaft 2648 and a driving part 2649. The support shaft 2648 may have a barrel shape formed in a third direction 16. An upper end of the support shaft 2648 may be securely coupled to a lower surface of the chuck 100. The driving part 2649 provides a driving force so that the support shaft 2648 is rotated. The support shaft 2648 is rotated by the driving part 2649, and the chuck 100 may be rotated together with the support shaft 2648.

The raising and lowering unit 2660 vertically moves the processing container 2620 in a vertical direction. As the processing container 2620 is vertically moved, a relative height of the processing container 2620 to the chuck 100 is changed. When the substrate W is loaded or unloaded on the chuck 100, the raising and lowering unit 2660 is operated such that the processing container 2620 is lowered so as to project the chuck 100 upward from the upper portion of the processing container 2620. Furthermore, during the process, depending on a type of the processing liquid supplied to the substrate W, the height of the processing container 2620 is adjusted, so that the processing liquid flows into the preset recovery container 2622, 2626. The raising and lowering unit 2660 includes a bracket 2662, a moving shaft 2664, and a driving unit 2666. The bracket 2662 is securely provided on an outer wall of the processing container 2620. The moving shaft 2664 may be securely coupled to the bracket 2662 and vertically moved by the driving unit 2666. The raising and lowering unit 2660 may selectively move the chuck 100 in the vertical direction.

The processing liquid supply unit 2680 supplies the processing liquid to the substrate W. The processing liquid supply unit 2680 may include a plurality of processing liquid supply units 2680. The processing liquid supply units 2680 may supply respectively different types of processing liquids.

The processing liquid supply unit 2680 may include a moving member 2681 and a nozzle 2690.

The moving member 2681 may move the nozzle 2690 to a process location and a waiting location. The process location may be a location where the nozzle 2690 faces an upper surface of the substrate W supported on the substrate support unit 2640. The waiting location may be a location where the nozzle 2690 is out of the process location.

The moving member 2681 may include a supporting shaft 2686, an arm 2674, and a driving device 2688. The supporting shaft 2686 is located at one side of the processing container 2620. The supporting shaft 2686 may have a rod shape extending in the third direction 16. The supporting shaft 2686 is provided to be rotatable by the driving device 2688. The supporting shaft 2686 may be provided to be movable in the vertical direction. The aim 2674 is coupled to an upper end of the supporting shaft 2686 and may perpendicularly extend from the supporting shaft 2686. The nozzle 2690 is securely coupled to an end of the arm 2674. As the supporting shaft 2686 is rotated, the nozzle 2690 may be swung with the arm 2674. The nozzle 2690 is swung to be moved to the process location and the waiting location. The arm 2674 may be provided to be selectively movable forward and rearward in a longitudinal direction thereof. In a view from the top, a route in which the nozzle 2690 is moved may coincide with a central shaft of the substrate W at the process location.

The substrate gripping apparatus for gripping the substrate according to the embodiment of the present disclosure may be provided as part of the substrate support unit 2640 in the substrate processing apparatus in FIG. 8. The substrate processing apparatus according to the embodiment of the present disclosure includes the substrate support unit 2640 supporting the substrate W, and the processing liquid supply unit 2680 supplying the chemical liquid to the substrate W. The substrate support unit 2640 may include the chuck 100, the support pins 500 provided on the chuck 100 and supporting the lower portion of the substrate W, the gear box 200 configured to be movable with respect to the chuck 100, the rotation gear 300 provided in the gear box 200, and the chuck pins 400 configured to be rotatable while being coupled to the rotation gear 300 and brought into contact with the lateral surface of the substrate W.

According to the embodiment of the present disclosure, the gear box 200 may include a gear box housing 210 providing a space in which the rotation gear 300 is arranged, and a linear guide 220 securely coupled to the chuck 100 and providing a path to rectilinearly move the gear box housing 210.

According to the embodiment of the present disclosure, the substrate support unit 2640 may include an angle adjustment gear 350 that is engaged with the rotation gear 300 and controls the rotation of the rotation gear 300.

According to the embodiment of the present disclosure, the angle adjustment gear 350 is coupled to the support pins 500 supporting the lower portion of the substrate W. The rotation of the chuck pins 400 may be controlled by the rotation of the support pins 500.

According to an embodiment of the present disclosure, the substrate support unit 2640 includes a worm gear 360. The worm gear 360 is engaged with the rotation gear 300 and is formed to extend to the outside of the gear box 200.

According to the embodiment of the present disclosure, the substrate support unit 2640 may include the driving source for rotating the worm gear 360.

According to the embodiment of the present disclosure, the substrate support unit 2640 may include a stopper holding the chuck pins 400 so as to prevent the rotation of the chuck pins 400.

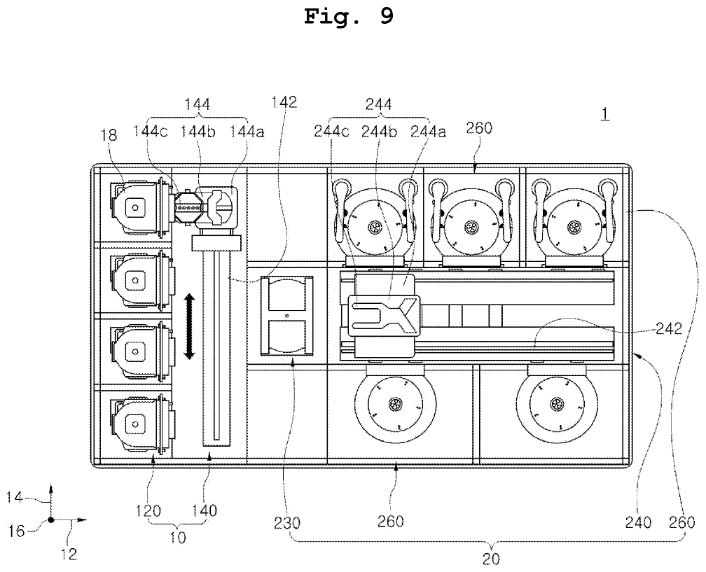

FIG. 9 is a view schematically showing a structure of substrate processing equipment.

Referring to FIG. 9, the substrate processing equipment 1 includes an index module 10 and a processing module 20. The index module 10 includes a load port 120 and a transfer frame 140. The load port 120, the transfer frame 140, and the processing module 20 are sequentially arranged in a line. Hereinbelow, a direction in which the load port 120, the transfer frame 140, and the processing module 20 are arranged is referred to a first direction 12. In a view from the top, a direction perpendicular to the first direction 12 is referred to a second direction 14. A direction perpendicular to a plane including the first direction 12 and the second direction 14 is referred to a third direction 16.

A carrier 18 storing the substrate W may be seated on the load port 120. The load port 120 may include a plurality of load ports 120, and the plurality of load ports 120 may be arranged in a line along the second direction 14. FIG. 9 is a view in which four load ports 120 are provided. However, the number of the load ports 120 may increase or decrease in response to conditions such as process efficiency of the processing module 20 and foot print. The carrier 18 has a slot (not shown) provided to support a rim of the substrate. The slot may include a plurality of a plurality of slots arranged along the third direction 16. The substrate is located in the carrier to be layered while being spaced apart from another substrate in the third direction 16.

A front opening unified pod (FOUP) may be used as the carrier 18.

The processing module 20 includes the buffer unit 230, a transfer chamber 240, a process chamber 260, and an exhaust assembly. The transfer chamber 240 is configured such that a longitudinal direction thereof is arranged in parallel to the first direction 12. Process chambers 260 are arranged on opposite sides of the transfer chamber 240 in the second direction 14. The process chambers 260 may be provided to be arranged symmetrically on the basis of the transfer chamber 240. Each of the process chambers 260 may include the substrate processing apparatus as shown in FIG. 8. Some of the process chambers 260 may be arranged in the longitudinal direction of the transfer chamber 240. Some of the process chambers 260 may be arranged to be layered with each other. On the opposite sides of the transfer chamber 240, the process chambers 260 are arranged in an arrangement of A×B (each of A and B is a natural number equal to or greater than 1). A is the number of the process chambers 260 provided in a line along the first direction 12. B is the number of the process chambers 260 provided in a line along the third direction 16. When four or six process chambers 260 are provided on each of the opposite sides of the transfer chamber 240, the process chambers 260 may have an arrangement of 2×2 or 3×2. The number of the process chambers 260 may increase or decrease.

Alternately, the process chambers 260 may be provided only on one side of the transfer chamber 240. The process chambers 260 may be provided on a first side or a second side of the transfer chamber 240 as a single layer. The process chamber 260 may be variously arranged as not described above. Some of the process chambers 260 provided on the first side of the transfer chamber 240 perform the liquid treatment process for the substrate. Some of the process chambers 260 provided on the second side of the transfer chamber 240 perform the drying process for the substrate that has been processed under the liquid treatment process. The drying process may be a supercritical process.

The buffer unit 230 is arranged between the transfer frame 140 and the transfer chamber 240. The buffer unit 230 provides a space in which the substrate W waits before being carried between the transfer chamber 240 and the transfer frame 140. The buffer unit 230 has slots (not shown) in which the substrate W is placed, and the plurality of slots (not shown) are provided to be spaced apart from each other in the third direction 16. The buffer unit 230 has a surface that faces the transfer frame 140 and is open and a surface that faces the transfer chamber 240 and is open.

The transfer frame 140 transfers the substrate W between the carrier 18 seated on each of the load ports 120 and the buffer unit 230. The transfer frame 140 has an index rail 142 and an index robot 144. The index rail 142 is provided such that a longitudinal direction thereof is parallel to the second direction 14. The index robot 144 is provided on the index rail 142, and is rectilinearly moved in the second direction 14 along the index rail 142. The index robot 144 includes a base 144a, a body 144b, and an index arm 144c. The base 144a is movably provided along the index rail 142. The body 144b is coupled to the base 144a. The body 144b is movably provided in the third direction 16 on the base 144a. The body 144b is rotatably provided on the base 144a. The index arm 144c is coupled to the body 144b, and is provided to be movable forward and rearward with respect to the body 144b. A plurality of index arms 144c may be provided and independently driven. The index arms 144c are arranged to be layered with each other while being spaced apart from each other in the third direction 16. Some of the index arms 144c may be used to transfer the substrate W from a processing module 20 to the carrier 18, and some of the index arms 144c may be used to transfer the substrate W from the carrier 18 to the processing module 20. Therefore, in a process of inserting and removing the substrate W by the index robot 144, particles generated on a substrate W before the process may be prevented from being attached to a substrate W after the process.

The transfer chamber 240 transfers the substrate W between the buffer unit 230 and the process chambers 260. The transfer chamber 240 includes a guide rail 242 and a main robot 244. The guide rail 242 may be arranged such that a longitudinal direction thereof is parallel to the first direction 12. The main robot 244 is provided on the guide rail 242 and rectilinearly moves in the first direction 12 on the guide rail 242.

The liquid processing apparatus according to the embodiment of the present disclosure may be realized as a part of the process chamber 260 described above. The substrate processing equipment 1 according to an embodiment of the present disclosure includes the index module 10 and the processing module 20. The index module 10 includes the load port 120 on which the carrier 18 storing the substrate W is seated and the transfer frame 140 transferring the substrate W, and the processing module 20 includes the buffer unit 230 on which the substrate W is temporarily loaded and the process chamber 260 in which the liquid treatment process for the substrate W is performed. The process chamber 260 includes the substrate support unit 2640 supporting the substrate W, and the processing liquid supply unit 2680 supplying the chemical liquid to the substrate W. The substrate support unit 2640 may include the chuck 100 configured to be rotatable, the support pins 500 secured on the chuck 100 and supporting the lower portion of the substrate W, the gear box 200 configured to be movable with respect to the chuck 100, the rotation gear 300 provided in the gear box 200, and the chuck pins 400 configured to be rotatable while being coupled to the rotation gear 300 and brought into contact with the lateral surface of the substrate W.

According to the embodiment of the present disclosure, the gear box 200 may include a gear box housing 210 providing a space in which the rotation gear 300 is arranged, and a linear guide 220 securely coupled to the chuck 100 and providing a path to rectilinearly move the gear box housing 210.

According to the embodiment of the present disclosure, the substrate support unit 2640 may include an angle adjustment gear 350 that is engaged with the rotation gear 300 and controls the rotation of the rotation gear 300.

According to the embodiment of the present disclosure, the angle adjustment gear 350 is coupled to the support pins 500 supporting the lower portion of the substrate W. The rotation of the chuck pins 400 may be controlled by the rotation of the support pins 500.

According to an embodiment of the present disclosure, the substrate support unit 2640 includes a worm gear 360. The worm gear 360 is engaged with the rotation gear 300 and is formed to extend to the outside of the gear box 200.

According to the embodiment of the present disclosure, the substrate support unit 2640 may include the driving source for rotating the worm gear 360.

According to the embodiment of the present disclosure, the substrate support unit 2640 may include a stopper holding the chuck pins 400 so as to prevent the rotation of the chuck pins 400.

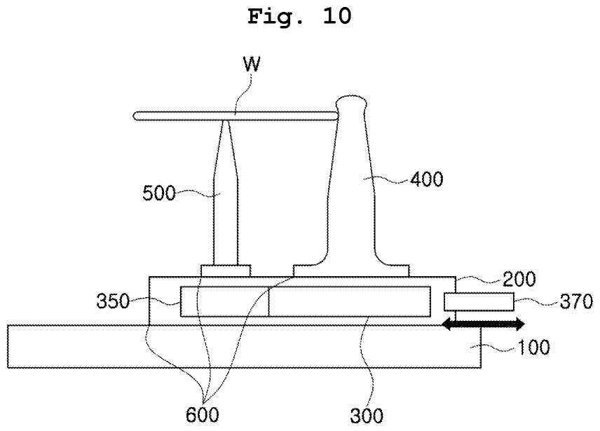

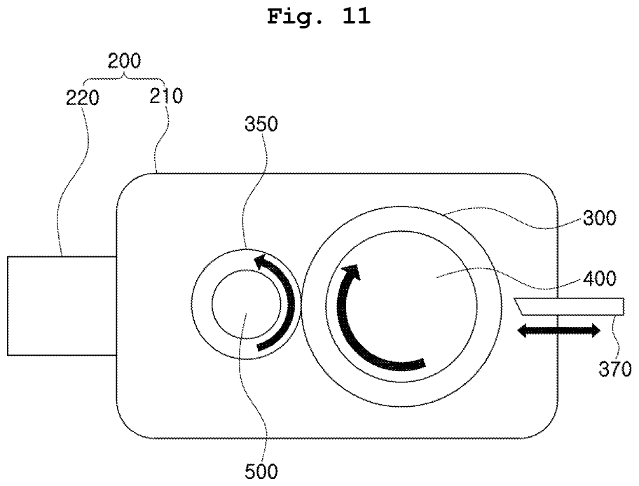

As shown in FIGS. 10 and 11, the stopper 370 is configured to selectively stop rotation of the rotation gear 300. The stopper 370 may be implemented as ball screw assembly capable move inward or outward of the gear box housing 210. When the stopper 370 is moved inward to contact with the rotation gear 300, the rotation gear 300 cannot be rotated. However, when the stopper 370 is moved outward being released from the rotation gear 300, the rotation gear 300 can be freely rotated.

Although the embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

The scope of the present disclosure will be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A substrate gripping apparatus for gripping a substrate in a substrate processing equipment, the substrate gripping apparatus comprising:
a chuck configured to rotate;
a gear box configured to be movable with respect to the chuck;
a rotation gear provided inside the gear box; and
a plurality of chuck pins connected to the rotation gear and configured to move toward a center of the chuck to secure the substrate,
wherein each chuck pin of the plurality of chuck pins rotatably contacts a corresponding portion of a lateral surface of the substrate.

2. The substrate gripping apparatus of claim 1,
wherein the gear box comprises:
a gear box housing providing a space to accommodate the rotation gear; and
a linear guide securely coupled to the chuck, and configured to provide a path for rectilinearly moving the gear box housing.

3. The substrate gripping apparatus of claim 1, further comprising:
an angle adjustment gear engaged with the rotation gear, and configured to rotate the rotation gear.

4. The substrate gripping apparatus of claim 3,
wherein the angle adjustment gear is coupled to a plurality of support pins configured to support a bottom surface of the substrate, and
wherein rotation of a chuck pin of the plurality of chuck pins is controlled by rotation of a support pin adjacent to the chuck pin.

5. The substrate gripping apparatus of claim 1, further comprising:
a worm gear engaged with the rotation gear, and extending to an outside of the gear box.

6. The substrate gripping apparatus of claim 5, further comprising:
a driving source configured to rotate the worm gear.

7. The substrate gripping apparatus of claim 1, further comprising:
a stopper configured to hold the plurality of chuck pins to prevent each chuck pin of the plurality of chuck pins from rotating.

8. The substrate gripping apparatus of claim 1, further comprising:
an oil seal disposed in a space between the chuck and the gear box so that the chuck and the gear box are coupled with each other using the oil seal,
wherein the oil seal prevents chemical liquid supplied to the substrate from leaking into the gear box.

9. A liquid processing apparatus comprising:
a substrate support unit configured to support a substrate; and
a processing liquid supply unit configured to supply chemical liquid to the substrate,
wherein the substrate support unit comprises:
a chuck configured to rotate;
a plurality of support pins secured to the chuck and configured to support a lower surface of the substrate;
a gear box configured to be movable with respect to the chuck;
a rotation gear provided inside the gear box; and
a plurality of chuck pins connected to the rotation gear and configured to move toward a center of the chuck to secure the substrate,
wherein each chuck pin of the plurality of chuck pins rotatably contacts a corresponding portion of a lateral surface of the substrate.

10. The liquid processing apparatus of claim 9,
wherein the gear box comprises:
a gear box housing providing a space to accommodate the rotation gear; and
a linear guide securely coupled to the chuck, and configured to provide a path for rectilinearly moving the gear box housing.

11. The liquid processing apparatus of claim 9, further comprising:
an angle adjustment gear engaged with the rotation gear, and configured to adjust rotation of the rotation gear.

12. The liquid processing apparatus of claim 11,
wherein the angle adjustment gear is coupled to the plurality of support pins, and
wherein rotation of a chuck pin of of the plurality of chuck pins is controlled by rotation of a support pin adjacent to the chuck pin.

13. The liquid processing apparatus of claim 9, further comprising:
a worm gear engaged with the rotation gear, and extending to an outside of the gear box.

14. The liquid processing apparatus of claim 13, further comprising:
a driving source configured to rotate the worm gear.

15. The liquid processing apparatus of claim 9, further comprising:
a stopper configured to hold the plurality of chuck pins to prevent each chuck pin of the plurality of chuck pins from rotating.

16. A substrate processing equipment comprising:
an index module comprising:
a load port configured to load a carrier storing a substrate, and
an index robot configured to transfer the substrate; and
a processing module comprising:
a buffer unit configured to load the substrate from the index robot, and
a process chamber in which a liquid treatment process is performed on the substrate loaded from the buffer unit, wherein the process chamber comprises:
a substrate support unit configured to support the substrate; and
a processing liquid supply unit configured to supply chemical liquid to the substrate, and
wherein the substrate support unit comprises:
a chuck configured to rotate;
a plurality of support pins secured to the chuck and configured to support a lower surface of the substrate;
a gear box configured to be movable with respect to the chuck;
a rotation gear provided inside the gear box; and
a plurality of chuck pins connected to the rotation gear and configured to move toward a center of the chuck to secure the substrate,
wherein each chuck pin of the plurality of chuck pins rotatably contacts a corresponding portion of a lateral surface of the substrate.

17. The substrate processing equipment of claim 16,
wherein the gear box comprises:
a gear box housing providing a space to accommodate the rotation gear; and
a linear guide securely coupled to the chuck, and configured to provide a path for rectilinearly moving the gear box housing.

18. The substrate processing equipment of claim 16, further comprising:
an angle adjustment gear engaged with the rotation gear, and configured to adjust rotation of the rotation gear.

19. The substrate processing equipment of claim 18,
wherein the angle adjustment gear is coupled to the plurality of support pins, and
wherein rotation of a chuck pin of the plurality of chuck pins is controlled by rotation of a support pin adjacent to the chuck pin.

20. The substrate processing equipment of claim 16, further comprising:
a worm gear engaged with the rotation gear, and extending to an outside of the gear box.
